(19) United States
(12) Patent Application Publication
(10) Pub. No.: US 2026/0262479 A1
(43) Pub. Date: Sep. 3, 2026

(54) SUBSTRATE PROCESSING APPARATUS AND SUPPLY APPARATUS

(71) Applicant: EBARA CORPORATION, Tokyo (JP)

(72) Inventors: MATSUTARO MIYAMOTO, Tokyo (JP); MAKOTO TAKAYAMA, Tokyo (JP)

(73) Assignee: EBARA CORPORATION, Tokyo (JP)

(21) Appl. No.: 19/539,067

(22) Filed: Feb. 13, 2026

(30) Foreign Application Priority Data
Feb. 28, 2025 (JP) 2025-030952

(51) Int. Cl. H10P 72/76; H10P 52/40; H10P 72/00

(52) U.S. Cl. CPC H10P 72/7618; H10P 52/40; H10P 72/0414

(57) ABSTRACT

A substrate processing apparatus includes a substrate processing table, a processing part, a supply line, and a swing mechanism. The processing part applies a predetermined processing to a substrate placed on an upper surface of the substrate processing table. The supply line includes a swing arm and a utility supply part. The swing arm extends toward above the upper surface of the substrate processing table. The utility supply part is inserted through the swing arm from outside the swing arm and supplies a utility to the substrate placed on the upper surface of the substrate processing table. The swing mechanism swings the swing arm about a swing axis. A part of the utility supply part extends along the swing axis and is positioned on the swing axis.

### CROSS-REFERENCE TO RELATED APPLICATION

This application claims the priority benefit of Japan application serial no. 2025-030952, filed on February 28, 2025. The entirety of the above-mentioned patent application is hereby incorporated by reference herein and made a part of this specification.

### BACKGROUND

### Technical Field

The disclosure relates to a substrate processing apparatus and a supply apparatus.

### Related Art

Conventionally, as disclosed in Patent Document 1 (Japanese Patent Application Laid-Open No. 2018-1374), a substrate processing apparatus is configured to process a substrate such as a silicon wafer. In such a substrate processing apparatus, a substrate is placed on a rotating table, and utilities such as pure water and an abrasive are supplied to the center of the table or the vicinity of the center of the table.

However, in the substrate processing apparatus described above, multiple pipings and the like are disposed at high density at the center of the table and in the vicinity of the center of the table. Therefore, in the substrate processing apparatus described above, it may be difficult to dispose further pipings for supplying utilities to the center of the table and the vicinity of the center of the table.

In addition, in a chemical-mechanical polishing (CMP) apparatus that polishes the surface of a substrate such as a silicon wafer to be flat, it has been newly discovered that supplying a large flow rate of pure water as a utility to the center of the table or the vicinity of the center of the table and performing polishing using the pure water creates effects such as reduction of particles generated by polishing. A piping for supplying such a large flow rate of pure water has a larger diameter than the pipings and the like in the substrate processing apparatus described above and thus has a lower flexibility, which may hinder swinging of a swing arm through which the piping is inserted.

### SUMMARY

(1) A substrate processing apparatus according to a first aspect of the disclosure includes a substrate processing table, a processing part, a supply line, and a swing mechanism. The processing part applies a predetermined processing to a substrate placed on an upper surface of the substrate processing table. The supply line includes a swing arm and a utility supply part. The swing arm extends from outside the substrate processing table toward a space above the substrate processing table. The utility supply part is inserted through the swing arm from outside the swing arm and supplies a utility to the substrate placed on the upper surface of the substrate processing table. The swing mechanism swings the swing arm about a swing axis. A part of the utility supply part extends along the swing axis and is positioned on the swing axis.
(2) In the substrate processing apparatus according to (1) above, the utility supply part may include a first utility piping, multiple second utility pipings, a third utility piping, a first piping connection part, and a second piping connection part. The first utility piping may extend along the swing axis and be positioned on the swing axis. The multiple second utility pipings may extend along the swing axis and be connected to the first utility piping. The third utility piping may have a part extending along the swing axis and positioned on the swing axis, be connected to the multiple second utility pipings, be inserted through the swing arm, and swing about the swing axis together with the swing arm. The first piping connection part may connect the first utility piping and the multiple second utility pipings. The second piping connection part may connect the multiple second utility pipings and the third utility piping.
(3) In the substrate processing apparatus according to (2) above, the second utility piping may have a higher flexibility than the first utility piping and the third utility piping.
(4) In the substrate processing apparatus according to (2) or (3) above, an outer diameter of the second utility piping may be smaller than each of an outer diameter of the first utility piping and an outer diameter of the third utility piping.
(5) In the substrate processing apparatus according to (2) to (4) above, a total of flow path areas of the multiple second utility pipings may be 80% or more of each of a flow path area of the first utility piping and a flow path area of the third utility piping.
(6) In the substrate processing apparatus according to (2) to (5) above, an upper end of the first utility piping may be fixed in a non-rotatable manner. Upon swinging of the swing arm about the swing axis, the multiple second utility pipings may twist such that a position of an upper end and a position of a lower end of each of the multiple second utility pipings differ from each other in a circumferential direction around the swing axis in a view in an up-down direction.
(7) In the substrate processing apparatus according to (2) to (6) above, in a view in an up-down direction, the multiple second utility pipings may be disposed to surround the swing axis.
(8) In the substrate processing apparatus according to (1) to (7) above, the utility supply part may supply a fluid as the utility.
(9) In the substrate processing apparatus according to (8) above, the utility supply part may supply pure water as the fluid.
(10) The substrate processing apparatus according to (1) to (9) above may further include a polishing head. A polishing pad may be attached to the upper surface of the substrate processing table, and a surface of the polishing pad may form a polishing surface for polishing the substrate. The polishing head may hold the substrate serving as a polishing target to polish the substrate while pressing the substrate against the polishing surface of the polishing pad on the substrate processing table.
(11) In the substrate processing apparatus according to (1) to (10) above, the supply line may further include a slurry supply part that is inserted through the swing arm from outside the swing arm and supplies a slurry to the upper surface of the substrate processing table.
(12) In the substrate processing apparatus according to (11) above, inside the swing arm, the slurry supply part may cross the utility supply part in a horizontal direction.
(13) In the substrate processing apparatus according to (11) or (12) above, a position on the upper surface of the substrate processing table at which the slurry supply part supplies the slurry may be closer to a center of the substrate processing table than a position on the upper surface of the substrate processing table at which the utility supply part supplies the utility.
(14) In the substrate processing apparatus according to (11) or (12) above, inside the swing arm, at least a part of the utility supply part may be disposed below the slurry supply part.
(15) In the substrate processing apparatus according to (1) to (14) above, the supply line may be provided in the processing part.
(16) The substrate processing apparatus according to (1) to (14) above may further include a dresser. The supply line may be provided in the dresser.
(17) A substrate processing apparatus according to a second aspect of the disclosure may include a substrate processing table, a processing part, a swing arm, a utility supply part, and a swing mechanism. The processing part may apply a predetermined processing to a substrate placed on an upper surface of the substrate processing table. The swing arm may extend from outside the substrate processing table toward a space above the substrate processing table. The utility supply part may be inserted through the swing arm from outside the swing arm and supply a utility to the swing arm. The swing mechanism may swing the swing arm about a swing axis. A part of the utility supply part may extend along the swing axis and be positioned on the swing axis.
(18) A supply apparatus according to a third aspect of the disclosure may be a supply apparatus supplying a utility to outside from a tip. The supply apparatus may include a supply line and a swing mechanism. The supply line may include a swing arm and a utility supply part. The swing arm may swing about a swing axis. The utility supply part may be inserted through the swing arm from outside the swing arm and supply the utility to outside from a tip of the swing arm. The swing mechanism may swing the swing arm about the swing axis. A part of the utility supply part may extend along the swing axis and be positioned on the swing axis.

According to an aspect of the disclosure, it is possible to provide a substrate processing apparatus and a supply apparatus in which a utility supply part is provided to supply a utility to at least a part of a swing arm or to outside the swing arm, and swinging of the swing arm through which the utility supply part is inserted is enabled.

### BRIEF DESCRIPTION OF THE DRAWINGS

FIG. 1 is a plan view showing an overall configuration of a substrate processing apparatus according to a first embodiment.

FIG. 2 is a perspective view showing a configuration of a polishing module provided in the substrate processing apparatus according to the first embodiment.

FIG. 3 is an enlarged perspective view of a supply line provided in the substrate processing apparatus according to the first embodiment.

FIG. 4 is a cross-sectional view of a main part of the supply line according to the first embodiment.

FIG. 5 is a plan view showing an arrangement relationship of the supply line, a polishing head, a dresser, and an atomizer on a substrate processing table according to the first embodiment.

FIG. 6 is a perspective view showing a configuration of a washing module provided in a substrate processing apparatus according to a second embodiment.

FIG. 7 is an enlarged perspective view showing a configuration of a dresser provided in a substrate processing apparatus according to a third embodiment.

FIG. 8 is a cross-sectional view of a main part of the dresser according to the third embodiment.

### DESCRIPTION OF THE EMBODIMENTS

Embodiments of the disclosure provide a substrate processing apparatus and a supply apparatus in which a utility supply part is provided to supply a utility to at least a part of a swing arm or to outside the swing arm, and swinging of the swing arm through which the utility supply part is inserted is enabled.

In the following description, an “up-down direction” does not necessarily coincide with a vertical direction. In addition, in the following description, a “horizontal direction” may deviate from a strictly defined horizontal direction.

### First Embodiment

Hereinafter, a substrate processing apparatus 1 according to a first embodiment of the disclosure will be described with reference to the drawings.

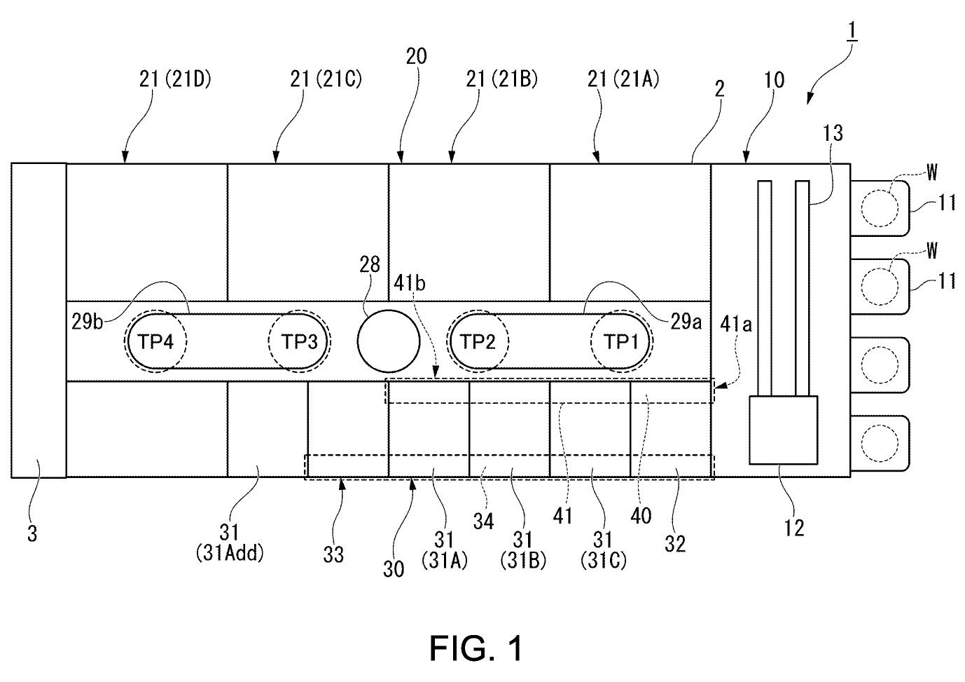

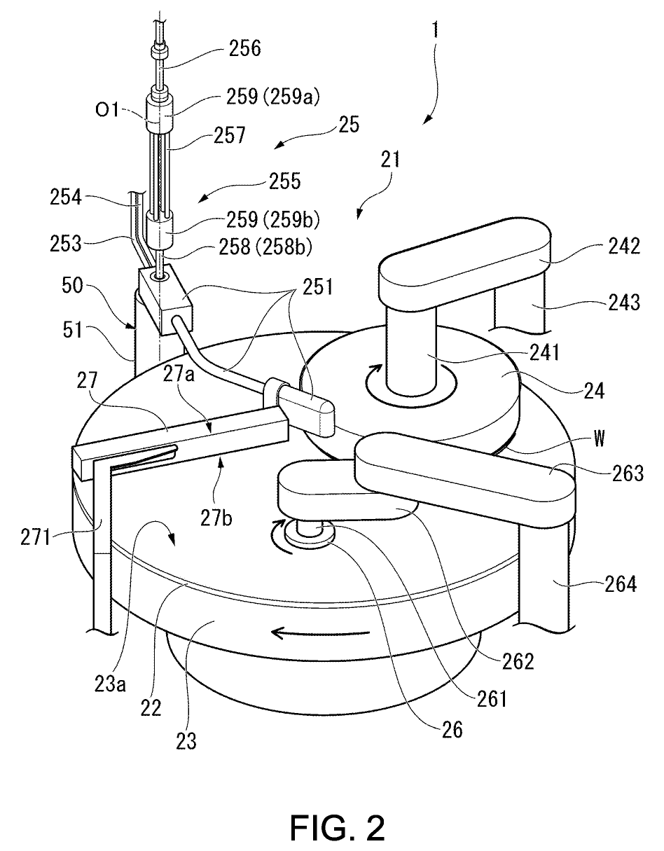

FIG. 1 is a plan view showing an overall configuration of the substrate processing apparatus 1 according to the first embodiment. FIG. 2 is a perspective view showing a configuration of a polishing module 21 provided in the substrate processing apparatus 1 according to the first embodiment.

The substrate processing apparatus 1 is a chemical-mechanical polishing (CMP) apparatus that polishes a surface of a substrate W such as a silicon wafer to be flat. As shown in FIG. 1, the substrate processing apparatus 1 includes a housing 2 in a rectangular box shape. The housing 2 is formed in a substantially rectangular shape in a plan view. The inside of the housing 2 is partitioned by partition walls into a load and unload part 10, a polishing part 20, and a washing part 30. In addition, the substrate processing apparatus 1 includes a substrate transport part 40 that transports the substrate W from the load and unload part 10 to the polishing part 20, and a control part 3 (control panel) that controls the operations of the load and unload part 10, the polishing part 20, the washing part 30, and the substrate transport part 40.

The load and unload part 10 includes a front load part 11 that accommodates the substrate W. Multiple front load parts 11 are provided on a lateral surface on one side in a longitudinal direction of the housing 2. The multiple front load parts 11 are arranged in a width direction (a direction orthogonal to the longitudinal direction in a plan view) of the housing 2. The front load part 11 is mounted with, for example, an open cassette, a standard mechanical interface (SMIF) pod, or a front opening unified pod (FOUP). The SMIF pod and the FOUP are sealed containers that accommodate a cassette of substrates W inside and are covered with partition walls, and are capable of maintaining an environment independent from the external space.

In addition, the load and unload part 10 includes a transport robot 12 that takes the substrate W into and out of the front load part 11, and a traveling mechanism 13 that causes the transport robot 12 to travel along the row of the front load parts 11. The transport robot 12 includes two hands on upper and lower sides, and uses the hands separately before and after processing of the substrate W. For example, the upper hand is used to return the substrate W to the front load part 11, and the lower hand is used to take out the substrate W before processing from the front load part 11.

The substrate transport part 40 includes a substrate transport path 41 extending in the longitudinal direction of the housing 2. The substrate transport path 41 passes through a region where the washing part 30 is disposed in a plan view, and has a one-end part 41a communicating with the load and unload part 10 and an other-end part 41b communicating with the polishing part 20. The substrate transport path 41 is provided with a slide stage that supports the substrate W, and a stage moving mechanism that moves the slide stage between the one-end part 41a and the other-end part 41b. The one-end part 41a is a loading port for the substrate W. The one-end part 41a is normally closed by a shutter, and is opened when accessed by the transport robot 12 of the load and unload part 10. In addition, the other-end part 41b is an unloading port for the substrate W. The other-end part 41b is normally closed by a shutter, and is opened when accessed by a transport robot 28 of the polishing part 20.

The polishing part 20 includes multiple polishing modules 21 (21A, 21B, 21C, and 21D) that polish the substrate W. The multiple polishing modules 21 are arranged in the longitudinal direction of the housing 2.

As shown in FIG. 2, the polishing module 21 includes a substrate processing table (polishing table) 23, a polishing head 24, a supply line 25, a dresser 26, an atomizer (processing part) 27, and a swing mechanism 50. The substrate processing table (polishing table) 23 has an upper surface (polishing surface) 23a formed of a polishing pad 22. The polishing head 24 serves to hold the substrate W, which is a polishing target, to polish the substrate W while pressing the substrate W against the upper surface 23a of the polishing pad 22 on the substrate processing table 23. The supply line 25 serves to supply a slurry (polishing liquid), a dressing liquid (e.g., pure water), and a large flow rate of pure water (utility) to the upper surface 23a of the substrate processing table 23. The dresser 26 serves to dress the upper surface 23a. The atomizer (processing part) 27 atomizes a liquid (e.g., pure water) or a mixed fluid of a liquid (e.g., pure water) and a gas (e.g., nitrogen gas) to inject onto the upper surface 23a. The swing mechanism 50 swings a swing arm 251 of the supply line 25 about a swing axis O1.

While supplying a slurry from a slurry supply part 253 inserted through the swing arm 251 of the supply line 25 to the upper surface 23a of the substrate processing table 23, the polishing module 21 presses the substrate W against the upper surface 23a with the polishing head 24 and further relatively moves the polishing head 24 and the substrate processing table 23 to thus polish the substrate W and planarize the surface of the substrate W. The dresser 26 has hard particles such as diamond particles or ceramic particles fixed to a rotating part at a tip that contacts the upper surface 23a. In addition, while supplying a large flow rate of pure water from a utility supply part 255 inserted through the swing arm 251 of the supply line 25 to the upper surface 23a of the substrate processing table 23, the polishing module 21 presses the substrate W against the upper surface 23a with the polishing head 24 and further relatively moves the polishing head 24 and the substrate processing table 23 to thus polish (water polish) the substrate W and planarize the surface of the substrate W. The polishing module 21 may polish the substrate W while simultaneously supplying a slurry and a large flow rate of pure water to the upper surface 23a of the substrate processing table 23, or may polish the substrate W while supplying only one of the slurry and the large flow rate of pure water to the upper surface 23a of the substrate processing table 23.

While a dressing liquid is supplied from a dressing liquid supply part 254 inserted through the swing arm 251 of the supply line 25 to the upper surface 23a of the substrate processing table 23, the dresser 26 swings and rotates a rotating part at the tip to thus uniformly dress the entire upper surface 23a and form a planar upper surface 23a. By washing away polishing debris, abrasive grains, etc. remaining on the upper surface 23a with a high-pressure fluid, the atomizer 27 achieves cleaning of the upper surface 23a and a dressing work of the upper surface performed by the dresser 26 in mechanical contact, i.e., achieving restoration of the upper surface 23a. That is, the atomizer 27, which is a processing part, applies a predetermined processing to the substrate W placed on the upper surface 23a of the substrate processing table 23.

Returning to FIG. 1, the polishing part 20 includes a transport robot 28, a first exchanger 29a, and a second exchanger 29b. In the polishing part 20, a first transport position TP1, a second transport position TP2, a third transport position TP3, and a fourth transport position TP4 are set sequentially from the load and unload part 10 side along the row of the multiple polishing modules 21. The first transport position TP1, the second transport position TP2, the third transport position TP3, and the fourth transport position TP4 are respectively positions for transferring the substrate W to the polishing module 21A, the polishing module 21B, the polishing module 21C, and the polishing module 21D. Each polishing module 21 accesses the first transport position TP1, the second transport position TP2, the third transport position TP3, or the fourth transport position TP4 by rotation of a support arm 242 (see FIG. 2) of the polishing head 24.

The transport robot 28 transfers the substrate W among the substrate transport part 40, the first exchanger 29a, and the second exchanger 29b. The transport robot 28 includes a hand that holds the substrate W, a reversing mechanism that flips the hand upside down, an extendable arm that supports the hand, an arm up-down moving mechanism that moves the arm in the up- down direction, an arm rotating mechanism that rotates the arm about an axis extending in the up-down direction, etc. The transport robot 28 is movable between the second transport position TP2 and the third transport position TP3, and distributes the substrate W received from the substrate transport part 40 to the first exchanger 29a or the second exchanger 29b. In addition, the transport robot 28 receives the substrate W polished by the polishing module 21 from the first exchanger 29a or the second exchanger 29b, and transfers the substrate W to the washing part 30.

The first exchanger 29a is a mechanism that transports the substrate W between the first transport position TP1 and the second transport position TP2. The first exchanger 29a includes multiple slide stages that support the substrate W, a stage moving mechanism that moves each of the slide stages in the horizontal direction at different heights, a first pusher disposed at the first transport position TP1, a second pusher disposed at the second transport position TP2, etc. Each slide stage has a notch part in a substantially reversed C-shape through which the first pusher and the second pusher are capable of passing in the up-down direction, and each slide stage moves between the first transport position TP1 and the second transport position TP2 by the stage moving mechanism. The first pusher moves in the up-down direction at the first transport position TP1, and transfers the substrate W between the slide stage and the polishing head 24 of the polishing module 21A. In addition, the second pusher moves in the up-down direction at the second transport position TP2, and transfers the substrate W between the slide stage and the polishing head 24 of the polishing module 21B.

The second exchanger 29b is a mechanism that transports the substrate W between the third transport position TP3 and the fourth transport position TP4. The second exchanger 29b includes multiple slide stages that support the substrate W, a stage moving mechanism that moves each of the slide stages in the horizontal direction at different heights, a third pusher disposed at the third transport position TP3, a fourth pusher disposed at the fourth transport position TP4, etc. Each slide stage has a notch part in a substantially reversed C-shape through which the third pusher and the fourth pusher are capable of passing in the up-down direction, and each slide stage moves

between the third transport position TP3 and the fourth transport position TP4 by the stage moving mechanism. The third pusher moves in the up-down direction at the third transport position TP3, and transfers the substrate W between the slide stage and the polishing head 24 of the polishing module 21C. In addition, the fourth pusher moves in the up-down direction at the fourth transport position TP4, and transfers the substrate W between the slide stage and the polishing head 24 of the polishing module 21D.

The washing part 30 includes multiple washing modules 31 (31A, 31B, 31C, and 31Add) that wash the substrate W, and a drying module 32 that dries the washed substrate W. The multiple washing modules 31 and the drying module 32 are arranged in the longitudinal direction of the housing 2. A transport chamber 33 (wafer station) is provided between the washing module 31A and the washing module 31Add. The transport chamber 33 is provided with a stage on which the substrate W transferred from the transport robot 28 is placed. In addition, the washing part 30 includes a washing part substrate transport mechanism 34 that picks up the substrate W placed on the stage of the transport chamber 33 and transports the substrate W among the multiple washing modules 31, the drying module 32, and the transport chamber 33.

The washing module 31A is disposed adjacent to the transport chamber 33 and performs primary washing on the substrate W. In addition, the washing module 31B is disposed adjacent to the washing module 31A and performs secondary washing on the substrate W. In addition, the washing module 31C is disposed adjacent to the washing module 31B and performs tertiary washing on the substrate W. The drying module 32 is disposed adjacent to the washing module 31C and performs, for example, Rotagoni drying (iso-propyl alcohol (IPA) drying). The washing module 31Add disposed on the opposite side of the washing module 31A with the transport chamber 33 interposed therebetween is added according to washing specifications, and performs, for example, preliminary washing on the substrate W before the washing processings of the washing modules 31A, 31B, and 31C.

The washing module 31 is composed of, for example, a roll washing module using a roll washing member, a pencil washing module using a pencil washing member, a two-fluid washing module using a two-fluid nozzle, etc. The washing modules 31 may be of the same type or may be different types of washing modules. Each of the washing modules 31 and the drying module 32 include an opening with a shutter through which the substrate W and the washing part substrate transport mechanism 34 transporting the substrate W are capable of passing. After drying, a shutter provided at a partition wall between the drying module 32 and the load and unload part 10 is opened, and the substrate W is taken out from the drying module 32 by the transport robot 12.

Next, the configuration of the polishing module 21 will be described in detail.

As described above, the polishing module 21 includes the substrate processing table 23, the polishing head 24, the supply line 25, the dresser 26, the atomizer (processing part, atomizer arm) 27, and the swing mechanism 50.

The substrate processing table 23 is connected to a substrate processing table rotating motor (not shown) disposed below the substrate processing table 23 via a table shaft, and is rotatable on the table shaft. The polishing pad 22 is attached to the upper surface of the substrate processing table 23, and the surface of the polishing pad 22 forms an upper surface (polishing surface) 23a for polishing the substrate W. For example, SUBA800, IC-1000, IC-1000/SUBA400 (two-layer cloth), etc. manufactured by Rodel, Inc. may be used as the polishing pad 22. SUBA800 is a non-woven fabric in which fibers are hardened with urethane resin. IC-1000 is a hard foamed polyurethane, is a pad having multiple fine pores on the surface, and is also called a perforated pad.

In the space above the substrate processing table 23, a swing arm 251 of the supply line 25 is installed, and a slurry (polishing liquid), a dressing liquid, and a large flow rate of pure water are supplied to the upper surface 23a of the polishing pad 22 on the substrate processing table 23 via a nozzle 251a provided at a tip of the swing arm 251 of the supply line 25. For example, a functional liquid containing silica (SiO₂) or ceria (CeO₂) as abrasive grains may be used as the slurry. For example, pure water may be used as the dressing liquid. The rear end of the swing arm 251 is supported by the shaft 51, and the swing arm 251 is swingable about the shaft 51.

The polishing head 24 is configured to be capable of holding the substrate W on the lower surface of the polishing head 24. The polishing head 24 is connected to a shaft 241, and the shaft 241 is configured to move up and down with respect to a support arm 242. With the up-down movement of the shaft 241, the polishing head 24 is moved up and down with respect to the support arm 242 and is positioned. The shaft 241 is configured to rotate by driving of a polishing head rotating motor (not shown). With the rotation of the shaft 241, the polishing head 24 rotates on the shaft 241.

The support arm 242 is configured to be turnable about a shaft 243, and the polishing head 24 is movable from a receiving position (first transport position TP1 to fourth transport position TP4 shown in FIG. 1) of the substrate W to above the substrate processing table 23 by the turning of the support arm 242. The polishing head 24 moved above the substrate processing table 23 presses the substrate W held on the lower surface against the upper surface 23a. At this time, the substrate processing table 23 and the polishing head 24 are respectively rotated, and a slurry and a large flow rate of pure water (utility) are supplied to the upper surface 23a from the slurry supply part 253 and the utility supply part 255 inserted through the swing arm 251 extending toward the space above the substrate processing table 23. In this manner, while the slurry and the large flow rate of pure water are supplied onto the polishing pad 22, the substrate W is pressed against the polishing pad 22, and the substrate W and the polishing pad 22 are moved relatively to each other to polish an insulating film, a metal film, etc. on the substrate W.

The dresser 26 includes a shaft 261, a dresser arm 262, and a support arm 263. The dresser 26 is connected to the shaft 261, and the shaft 261 is rotatably attached to a tip of the dresser arm 262. The dresser 26 has a circular dressing surface, and hard particles are fixed to the dressing surface by electrodeposition or the like. Examples of such hard particles include diamond particles and ceramic particles. A motor (not shown) is built into the dresser arm 262, and the dresser 26 is rotated by the motor. The other end of the dresser arm 262 is swingably connected to the support arm 263, and the support arm 263 is swingably supported by a dresser swing mechanism 264.

When dressing the upper surface 23a, the substrate processing table 23 is rotated, the dresser 26 is rotated by the motor (not shown), then the dresser 26 is lowered by a lifting mechanism (not shown), and the lower surface of the dresser 26 is brought into sliding contact with the upper surface 23a which rotates. In such a state, by swinging the dresser arm 262 and the support arm 263, the dresser 26 is capable of moving across from an outer circumferential end to a center part of the upper surface 23a. At this time, a dressing liquid is supplied to the upper surface 23a from the dressing liquid supply part 254 inserted through the swing arm 251 of the supply line 25. In this manner, while the dressing liquid is supplied to the upper surface 23a, the dresser 26 is capable of dressing over the entire upper surface 23a including the center of the upper surface 23a.

It is also possible that the dresser 26 does not include the dresser arm 262. In such a case, the shaft 261 is rotatably attached to the tip of the support arm 263, a motor (not shown) is built into the support arm 263, and the dresser 26 is rotated by the motor.

The atomizer 27 is disposed above the polishing pad 22 and is disposed to extend in a substantially radial direction of the substrate processing table 23 parallel to the upper surface 23a. The atomizer 27 extends to outside the substrate processing table 23 and is fixed to the housing 2 (see FIG. 1) or the like via an atomizer swing mechanism 271. The atomizer 27 includes injection ports (not shown) on a lower surface 27b opposed to the upper surface 23a. Multiple injection ports are provided, for example, at a predetermined pitch along the longitudinal direction of the atomizer 27.

The atomizer 27 is connected to a pure water supply line (not shown). The pure water supply line is provided with a control valve, and a control signal is inputted to the control valve from the control part 3, which is a CMP controller, to control the flow rate of pure water injected from the injection ports. Accordingly, pure water at an optimal flow rate is sprayed onto the upper surface 23a, and foreign matter (polishing pad residue, abrasive liquid deposits, etc.) on the upper surface 23a is removed. In the case of injecting a mixed fluid from the injection ports, the atomizer 27 is also connected to a gas source.

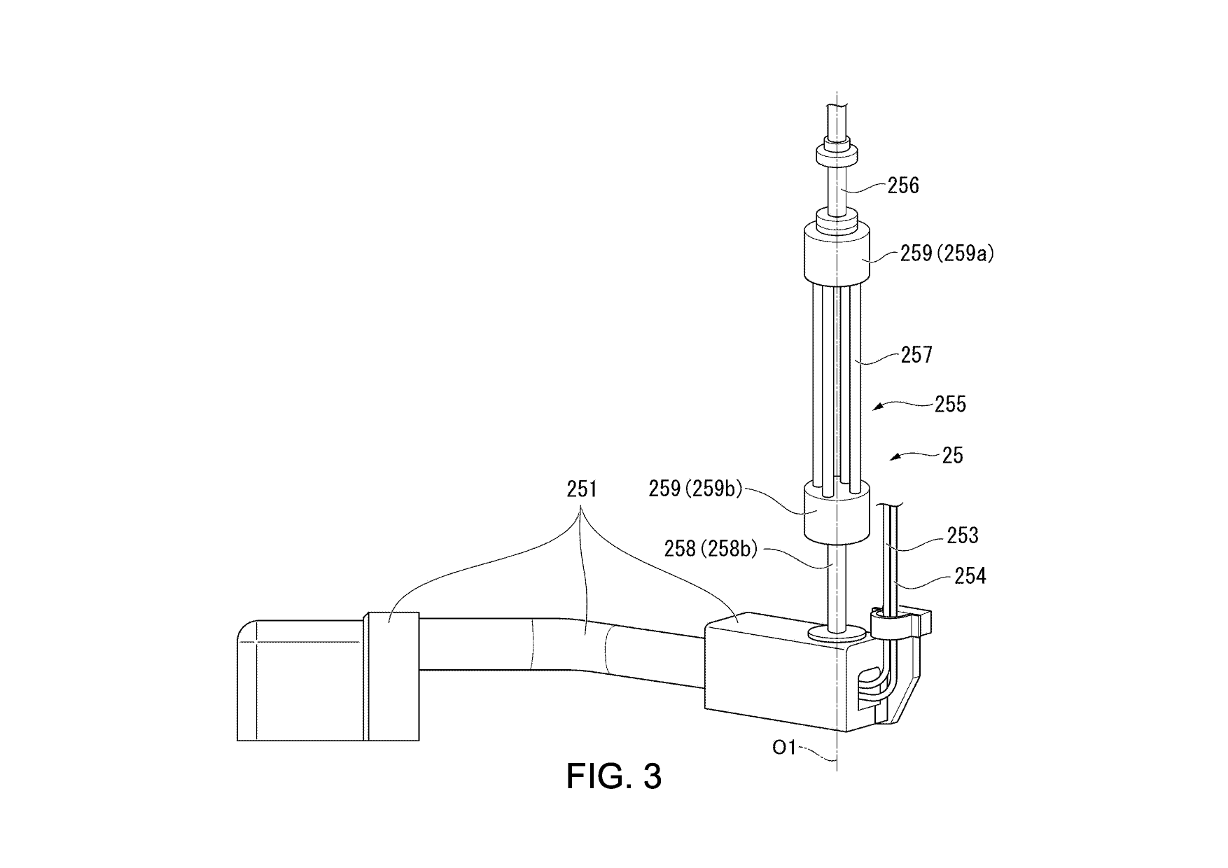

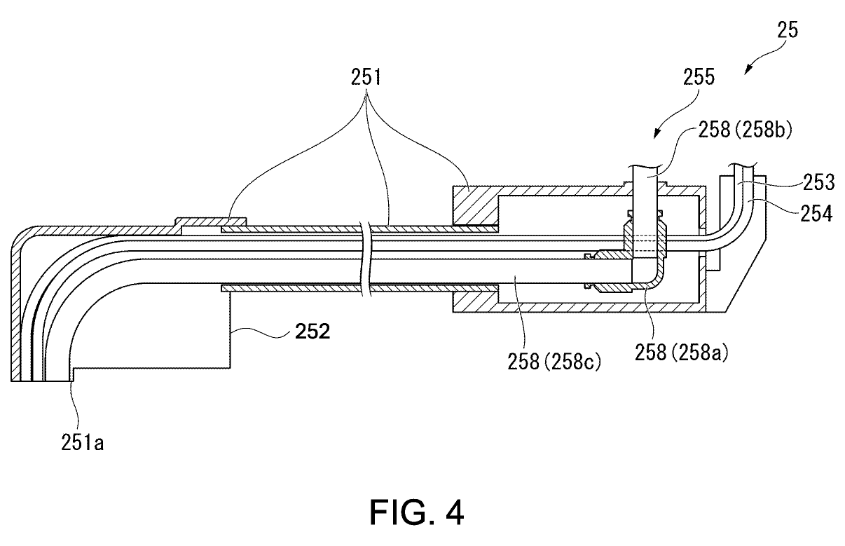

FIG. 3 is an enlarged perspective view of the supply line 25 according to the present embodiment. FIG. 4 is a cross-sectional view of a main part of the supply line 25 according to the present embodiment. The supply line 25 includes the swing arm 251, the slurry supply part 253, the dressing liquid supply part 254, and the utility supply part 255.

The swing arm 251 is provided at the upper end of the shaft 51 and extends in the horizontal direction. The swing arm 251 extends from outside the substrate processing table 23 toward the space above the substrate processing table 23. The swing arm 251 is formed in a shape having a cavity inside, and the slurry supply part 253, the dressing liquid supply part 254, and the utility supply part 255 are inserted through inside of the swing arm 251. The swing arm 251 supports the slurry supply part 253, the dressing liquid supply part 254, and the utility supply part 255 inserted through inside of the swing arm 251. A nozzle 251a, which is a discharge part, is provided at the tip of the swing arm 251 on the center side of the substrate processing table 23.

The slurry supply part 253 is a piping that is inserted through the swing arm 251 from outside the swing arm 251 and supplies a slurry from the nozzle 251a to the upper surface 23a of the substrate processing table 23. The slurry supply part 253 is formed of a flexible tube body. The slurry supply part 253 is inserted inside the swing arm 251 from a lateral surface of the swing arm 251 at the rear end opposite to the tip (one end at which the nozzle 251a is provided) of the swing arm 251, and the slurry supply part 253 extends in the horizontal direction. A tip of the slurry supply part 253 bends downward inside the swing arm 251, is exposed to outside on the lower surface of the swing arm 251, and drips the slurry onto the upper surface 23a of the substrate processing table 23 as the nozzle 251a.

The dressing liquid supply part 254 is a piping that is inserted through the swing arm 251 from outside the swing arm 251 and supplies a dressing liquid to the upper surface 23a of the substrate processing table 23. The dressing liquid supply part 254 is formed of a flexible tube body. In the case of supplying pure water as the dressing liquid, the dressing liquid supply part 254 supplies, for example, 0.5 L/min to 1.5 L/min of pure water. The dressing liquid supply part 254 is inserted inside the swing arm 251 from the lateral surface of the swing arm 251 at the rear end opposite to the nozzle 251a located at the tip of the swing arm 251, and the dressing liquid supply part 254 extends in the horizontal direction. A tip of the dressing liquid supply part 254 bends downward inside the swing arm 251, is exposed to outside on the lower surface of the swing arm 251, and drips the dressing liquid onto the upper surface 23a of the substrate processing table 23 as the nozzle 251a.

At least one of the slurry supply part 253 and the dressing liquid supply part 254 may be configured such that a part thereof extends along the swing axis O1 and is positioned on the swing axis O1. In such a case, at least one of the slurry supply part 253 and the dressing liquid supply part 254 extends downward from an upper end in the up-down direction and is inserted through inside of the swing arm 251 from the upper surface of the swing arm 251.

The utility supply part (DIW supply part) 255 is a piping that is inserted through the swing arm 251 from outside the swing arm 251 and supplies a large flow rate of pure water (de-ionized water, DIW), which is a fluid, as a utility to the upper surface 23a of the substrate processing table 23. The utility supply part 255 supplies, for example, 0.5 L/min to 10 L/min of pure water. Preferably, the utility supply part 255 supplies 10 L/min of pure water. In the case where the dressing liquid supply part 254 supplies pure water as the dressing liquid, the amount of pure water supplied by the utility supply part 255 is greater than the amount of pure water supplied by the dressing liquid supply part 254.

The utility supply part 255 includes a first utility piping (first DIW piping) 256, multiple second utility pipings (multiple second DIW pipings) 257, a third utility piping (third DIW piping) 258, and multiple piping connection parts 259 (first piping connection part 259a and second piping connection part 259b).

The first piping connection part 259a connects the first utility piping 256 and the multiple second utility pipings 257. The second piping connection part 259b connects the multiple second utility pipings 257 and the third utility piping 258.

The first utility piping 256 has an upper end fixed in a non-rotatable manner, and a lower end connected to the multiple second utility pipings 257 by the first piping connection part 259a.

The multiple second utility pipings 257 have upper ends connected to the first utility piping 256 by the first piping connection part 259a, and lower ends connected to the third utility piping 258 (piping 258b) by the second piping connection part 259b. In the present embodiment, four second utility pipings 257 are provided, but the number of the second utility pipings 257 provided may also be any number of two or more.

The third utility piping 258 has an upper end connected to the second utility pipings by the second piping connection part 259b, extends downward from the upper end in the up-down direction, and is inserted into the swing arm 251 from the upper surface of the swing arm 251. The third utility piping 258 swings about the swing axis O1 together with the swing arm 251. The third utility piping 258 includes a joint 258a and multiple pipings 258b and 258c, and is configured by connecting the multiple pipings 258b and 258c with the joint 258a.

The joint 258a bends at a right angle (90°). The joint 258a may also bend at an angle (e.g., 45°, 60°, etc.) other than a right angle. The piping 258b has an upper end connected to the second utility pipings by the second piping connection part 259b, and a lower end inserted into the swing arm 251 and connected to the piping 258c by the joint 258a. The piping 258c is inserted into the swing arm 251, and one end of the piping 258c is connected to the piping 258b by the joint 258a. The piping 258c extends in the horizontal direction from the joint 258a, and the other end (tip) of the piping 258c bends downward inside a tip block 252, is exposed to outside on the lower surface of the tip block 252, and drips pure water onto the upper surface 23a of the substrate processing table 23 as the nozzle 251a.

The first utility piping 256 and a part (piping 258b) of the third utility piping 258 extend along the swing axis O1 and are positioned on the swing axis O1. That is, a part of the utility supply part 255 extends along the swing axis O1 and is positioned on the swing axis O1. In a view in the up-down direction (a view in the swing axis O1 direction), the first utility piping 256 and the piping 258b of the third utility piping 258 overlap with the swing axis O1.

The first piping connection part 259a and the second piping connection part 259b are positioned on the swing axis O1 and overlap with the swing axis O1 in a view in the up-down direction. In addition, the multiple second utility pipings 257 extend along the swing axis O1 and are disposed to surround the swing axis O1 in a view in the up-down direction.

The first utility piping 256, the multiple second utility pipings 257, and the third utility piping 258 (pipings 258b and 258c) are formed of flexible tube bodies.

The first utility piping 256 and the third utility piping 258 (pipings 258b and 258c) have the same inner diameter, outer diameter, and flow path area. The inner diameter, the outer diameter, and the flow path area of the first utility piping 256 and the third utility piping 258 (pipings 258b and 258c) are larger than the inner diameter, the outer diameter, and the flow path area of the slurry supply part 253 and the dressing liquid supply part 254.

The first utility piping 256 and the third utility piping 258 (pipings 258b and 258c) may also have inner diameters, outer diameters, and flow path areas different from each other.

In addition, at least one of the inner diameter, the outer diameter, and the flow path area of the first utility piping 256 and the third utility piping 258 (pipings 258b and 258c) may be the same as at least one of the inner diameter, the outer diameter, and the flow path area of the slurry supply part 253 and the dressing liquid supply part 254.

On the other hand, the inner diameter, the outer diameter, and the flow path area of the second utility piping 257 are respectively smaller than the inner diameter, the outer diameter, and the flow path area of the first utility piping 256 and the third utility piping 258 (pipings 258b and 258c).

Since the outer diameter of the second utility piping 257 is smaller than each of the outer diameter of the first utility piping 256 and the outer diameter of the third utility piping 258 (pipings 258b and 258c), the second utility piping 257 has a higher flexibility than the first utility piping 256 and the third utility piping 258 (pipings 258b and 258c). That is, the second utility piping 257 bends and twists more easily than the first utility piping 256 and the third utility piping 258 (pipings 258b and 258c).

The multiple second utility pipings 257 are configured such that the total of the flow path areas of the multiple second utility pipings 257 is substantially the same as the flow path area of each of the first utility piping 256 and the third utility piping 258 (pipings 258b and 258c). Specifically, the multiple second utility pipings 257 are configured such that the total of the flow path areas of the multiple second utility pipings 257 is 80% or more of each of the flow path area of the first utility piping 256 and the flow path area of the third utility piping 258 (pipings 258b and 258c).

With the utility supply part 255 configured as described above, the pure water supplied from outside to the first utility piping 256 is branched by the first piping connection part 259a and supplied to the multiple second utility pipings 257. Then, the utility supply part 255 merges the pure water branched and supplied to the multiple second utility pipings 257 by the second piping connection part 259b and supplies the pure water to the third utility piping 258 (piping 258b).

As shown in FIG. 4, the slurry supply part 253 and the dressing liquid supply part 254 are inserted inside the swing arm 251 from a position further on the side opposite to the tip (one end at which the nozzle 251a is provided) of the swing arm 251 than the utility supply part 255 (third utility piping 258, piping 258b). Therefore, inside the swing arm 251, the slurry supply part 253 and the dressing liquid supply part 254 cross the utility supply part 255 (third utility piping 258, piping 258b) in the horizontal direction. That is, inside the swing arm 251, when viewed from a direction orthogonal to the up-down direction and the extending direction of the piping 258c along the horizontal direction (in the cross-sectional view shown in FIG. 4), the slurry supply part 253 and the dressing liquid supply part 254 intersect with the utility supply part 255 (third utility piping 258, piping 258b).

Inside the swing arm 251, the slurry supply part 253 and the dressing liquid supply part 254 may be bent to cross the utility supply part 255 (third utility piping 258, piping 258b). Inside the swing arm 251, the slurry supply part 253 and the dressing liquid supply part 254 may surround (encircle) the utility supply part 255 (third utility piping 258, piping 258b). That is, inside the swing arm 251, the slurry supply part 253 and the dressing liquid supply part 254 may sandwich the piping 258c from both sides in a direction orthogonal to the up-down direction and the extending direction of the piping 258c along the horizontal direction.

In addition, as shown in FIG. 4, inside the swing arm 251, the utility supply part 255 (third utility piping 258, piping 258c) is positioned below the slurry supply part 253 and the dressing liquid supply part 254.

Inside the swing arm 251, the utility supply part 255 (third utility piping 258, piping 258c) may also be positioned above the slurry supply part 253 and the dressing liquid supply part 254.

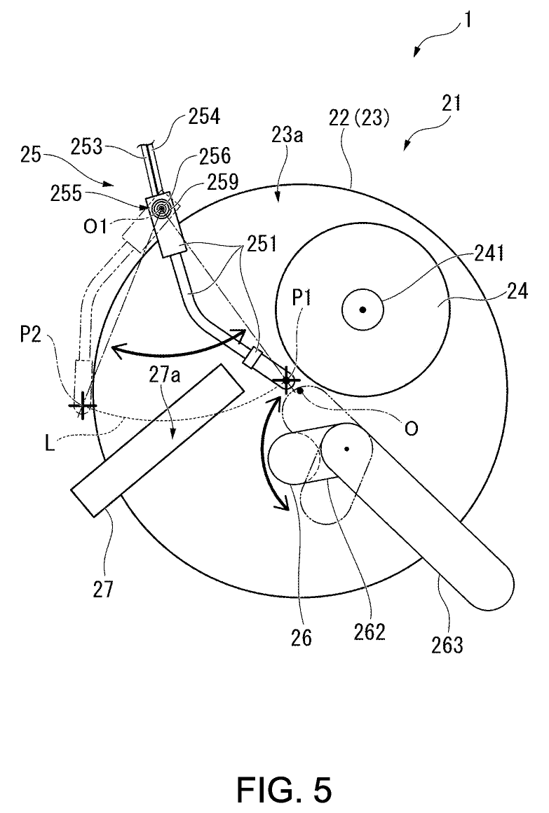

FIG. 5 is a plan view showing an arrangement relationship of the supply line 25, the polishing head 24, the dresser 26, and the atomizer 27 on the substrate processing table 23 according to the present embodiment.

As shown in FIG. 5, the polishing head 24, the dresser 26, and the atomizer 27 are disposed to divide the space on the polishing pad 22 into three parts in the circumferential direction centered on the rotation center O of the substrate processing table 23. The polishing head 24 and the atomizer 27 are disposed on sides opposite to each other with the rotation center O of the substrate processing table 23 positioned therebetween. In addition, the supply line 25 is disposed adjacent to the polishing head 24 and the atomizer 27, and supplies the slurry, the dressing liquid, and the pure water to a fluid dripping position P1 on the upper surface 23a of the substrate processing table 23.

The fluid dripping position P1 is set in the vicinity of the rotation center O of the substrate processing table 23. The fluid dripping position P1 may coincide with the rotation center O of the substrate processing table 23, or the rotation center O of the substrate processing table 23 may overlap with the fluid dripping position P1. In addition, the fluid dripping position P1 may also be a region occupying a specific range on the upper surface 23a of the substrate processing table 23.

The position on the upper surface 23a of the substrate processing table 23 at which the slurry supply part 253 supplies the slurry (i.e., dripping position of the slurry dripped by the slurry supply part 253), the position on the upper surface 23a of the substrate processing table 23 at which the dressing liquid supply part 254 supplies the dressing liquid (i.e., dripping position of the dressing liquid dripped by the dressing liquid supply part 254), and the position on the upper surface 23a of the substrate processing table 23 at which the utility supply part 255 supplies the pure water (i.e., dripping position of the pure water dripped by the utility supply part 255) do not necessarily completely coincide with each other, as long as such positions overlap with the fluid dripping position P1.

In the present embodiment, as shown in FIG. 3 and FIG. 5, the dripping position of the slurry dripped by the slurry supply part 253 is closer to the rotation center O of the substrate processing table 23 than the dripping position of the dressing liquid dripped by the dressing liquid supply part 254 and the dripping position of the pure water dripped by the utility supply part 255. In addition, the dripping position of the dressing liquid dripped by the dressing liquid supply part 254 is closer to the rotation center O of the substrate processing table 23 than the dripping position of the pure water dripped by the utility supply part 255.

The dripping position of the dressing liquid dripped by the dressing liquid supply part 254 may also be closer to the rotation center O of the substrate processing table 23 than the dripping position of the slurry dripped by the slurry supply part 253. In addition, the dripping position of the pure water dripped by the utility supply part 255 may also be closer to the rotation center O of the substrate processing table 23 than the dripping position of the slurry dripped by the slurry supply part 253 and the dripping position of the dressing liquid dripped by the dressing liquid supply part 254.

The swing arm 251 of the supply line 25 is configured to be swingable about the shaft 51. In the plan view shown in FIG. 5, the shaft 51 constitutes a swing mechanism 50 that swings the swing arm 251 of the supply line 25 along a swing path L between a retract position P2 set outside the substrate processing table 23 and the fluid dripping position P1. The swing mechanism 50 includes the shaft 51 and a rotation drive part (not shown). The rotation drive part includes a motor outside the substrate processing table 23 to rotate the shaft 51 on the swing axis O1 extending in the up-down direction. Upon rotation of the shaft 51, the swing arm 251 of the supply line 25 swings about the swing axis O1 (about the shaft 51) as shown in FIG. 5. That is, the swing mechanism 50 swings the swing arm 251 about the swing axis O1.

As shown in FIG. 2, at least a part of the swing arm 251 of the supply line 25 is disposed low than the upper surface 27a of the atomizer 27. That is, the atomizer 27 is disposed higher than the swing path L of the supply line 25. The supply line 25 is configured to drip the slurry, the dressing liquid, and the pure water at a position lower than the upper surface 27a of the atomizer 27 at the fluid dripping position P1 set on the substrate processing table 23. The swing arm 251 of the supply line 25 is configured to be movable in the up-down direction, or is configured to be rotationally movable about an axis extending in the horizontal direction. Therefore, by moving upward, the swing arm 251 is configured not to interfere with the atomizer 27 in the case of swinging along the swing path L.

The entire swing arm 251 may also be positioned higher than the upper surface 27a of the atomizer 27. In such a case, even without moving upward, the swing arm 251 does not interfere with the atomizer 27 in the case of swinging along the swing path L. In addition, in such a case, it is possible that the swing arm 251 is not configured to be movable in the up-down direction, or is not configured to be rotationally movable about an axis extending in the horizontal direction.

Upon swinging of the swing arm 251 about the swing axis O1, parts of the slurry supply part 253 and the dressing liquid supply part 254 positioned inside the swing arm 251 also swing about the swing axis O1. At the same time, in conjunction with the swing motion, parts of the slurry supply part 253 and the dressing liquid supply part 254 not positioned inside the swing arm 251 also twists or flexes.

Upon swinging of the swing arm 251 about the swing axis O1, a part of the utility supply part 255 positioned inside the swing arm 251 also swings about the swing axis O1. That is, upon swinging of the swing arm 251 about the swing axis O1, the piping 258c of the third utility piping 258 also swings about the swing axis O1.

Upon swinging of the piping 258c of the third utility piping 258 about the swing axis O1, in conjunction with such swing motion, the piping 258b of the third utility piping 258 rotates in place in a twisting manner, and the second piping connection part 259b rotates in place. Then, the multiple second utility pipings 257 twist, the first piping connection part 259a rotates in place, and the first utility piping 256 rotates in place in a twisting manner.

Herein, in the case where the swing arm 251 swings about the swing axis O1, the multiple second utility pipings 257 twist such that the positions of the upper end and the lower end of each of the multiple second utility pipings 257 in a view in the up-down direction (a view in the swing axis O1 direction) differ (shift) from each other in the circumferential direction around the swing axis O1. Accordingly, the utility supply part 255 allows the swing motion of the swing arm 251 centered on the swing axis O1.

That is, by providing multiple second utility pipings 257 each having small inner diameter and outer diameter and high flexibility (bending and twisting easily) between the first utility piping 256 and the third utility piping 258 having large inner diameter and outer diameter, it is possible to supply a large flow rate of pure water by the utility supply part 255 while enabling the swing arm 251 to swing about the swing axis O1.

As described above, the substrate processing apparatus 1 of the present embodiment includes: the substrate processing table 23; the processing part 27 that applies a predetermined processing to the substrate W placed on the upper surface 23a of the substrate processing table 23; the supply line 25 having the swing arm 251 that extends from outside the substrate processing table 23 toward a space above the substrate processing table 23, and the utility supply part 255 that is inserted through the swing arm 251 from outside the swing arm 251 and supplies a utility to the substrate W placed on the upper surface 23a of the substrate processing table 23; and the swing mechanism 50 that swings the swing arm 251 about the swing axis O1. A part of the utility supply part 255 extends along the swing axis O1 and is positioned on the swing axis O1. With such a configuration, while the utility supply part 255 supplying the utility to the substrate processing table 23 is provided, it is possible to provide a substrate processing apparatus 1 that enables swinging of the swing arm 251 through which the utility supply part 255 is inserted.

In addition, the utility supply part 255 includes: the first utility piping 256 extending along the swing axis O1 and positioned on the swing axis O1; the multiple second utility pipings 257 extending along the swing axis O1 and connected to the first utility piping 256; the third utility piping 258 that has a part extending along the swing axis O1 and positioned on the swing axis O1, is connected to the multiple second utility pipings 257, is inserted through the swing arm 251, and swings about the swing axis O1 together with the swing arm 251; the first piping connection part 259a connecting the first utility piping 256 and the multiple second utility pipings 257; and the second piping connection part 259b connecting the multiple second utility pipings 257 and the third utility piping 258. With such a configuration, the swing arm 251 through which the utility supply part 255 is inserted can be configured to swing more easily.

In addition, the second utility piping 257 has a higher flexibility than the first utility piping 256 and the third utility piping 258. With such a configuration, the second utility piping 257 can be configured to bend and twist easily, and the swing arm 251 through which the utility supply part 255 is inserted can be configured to swing more easily.

In addition, the outer diameter of the second utility piping 257 is smaller than each of the outer diameter of the first utility piping 256 and the outer diameter of the third utility piping 258. With such a configuration, the second utility piping 257 has a high flexibility, the second utility piping 257 can be configured to bend and twist easily, and the swing arm 251 through which the utility supply part 255 is inserted can be configured to swing more easily.

In addition, the total of the flow path areas of the multiple second utility pipings 257 is 80% or more of each of the flow path area of the first utility piping 256 and the flow path area of the third utility piping 258. With such a configuration, while the swing arm 251 through which the utility supply part 255 is inserted is configured to swing easily, a sufficient amount of the utility can be supplied via the utility supply part 255.

In addition, the upper end of the first utility piping 256 is fixed in a non-rotatable manner, and in the case where the swing arm 251 swings about the swing axis O1, the multiple second utility pipings 257 twist such that the position of the upper end and the position of the lower end of each of the multiple second utility pipings 257 differ from each other in the circumferential direction around the swing axis O1 in a view in the up-down direction. With such a configuration, with the multiple second utility pipings 257 twisting, the swing arm 251 through which the utility supply part 255 is inserted can be configured to swing more easily.

In addition, in a view in the up-down direction, the multiple second utility pipings 257 are disposed to surround the swing axis O1. With such a configuration, instead of the case where only a part of the multiple second utility pipings 257 twists, each of the multiple second utility pipings 257 is configured to twist easily, and thus the swing arm 251 through which the utility supply part 255 is inserted can be configured to swing more easily.

In addition, the utility supply part 255 supplies a fluid as the utility. With such a configuration, while enabling swinging of the swing arm 251 through which the utility supply part 255 is inserted, a fluid can be supplied as the utility to the upper surface 23a of the substrate processing table 23.

In addition, the utility supply part 255 supplies pure water as the fluid. With such a configuration, while enabling swinging of the swing arm 251 through which the utility supply part 255 is inserted, pure water can be supplied as the utility to the upper surface 23a of the substrate processing table 23.

In addition, the utility supply part 255 further includes the slurry supply part 253 that is inserted through the swing arm 251 from outside the swing arm 251 and supplies a slurry to the upper surface 23a of the substrate processing table 23. With such a configuration, while enabling swinging of the swing arm 251 through which the utility supply part 255 is inserted, a slurry can be supplied together with the utility to the upper surface 23a of the substrate processing table 23.

In addition, inside the swing arm 251, the slurry supply part 253 crosses the utility supply part 255 in the horizontal direction. With such a configuration, while both the slurry supply part 253 and the utility supply part 255 are inserted through the swing arm 251, the slurry supply part 253 and the utility supply part 255 can be efficiently arranged.

In addition, the position on the upper surface 23a of the substrate processing table 23 at which the slurry supply part 253 supplies the slurry is closer to the center of the substrate processing table 23 than the position on the upper surface 23a of the substrate processing table 23 at which the utility supply part 255 supplies the utility. With such a configuration, the slurry can be supplied to a position closer to the center of the substrate processing table 23 on the upper surface 23a of the substrate processing table 23.

In addition, inside the swing arm 251, at least a part of the utility supply part 255 is disposed below the slurry supply part 253. With such a configuration, inside the swing arm 251, since the utility supply part 255 can be supported upward by the lower surface of the swing arm 251, the utility can be stably supplied to the substrate processing table 23 via the utility supply part 255.

### Second Embodiment

Hereinafter, a substrate processing apparatus 1A according to a second embodiment of the disclosure will be described with reference to the drawings.

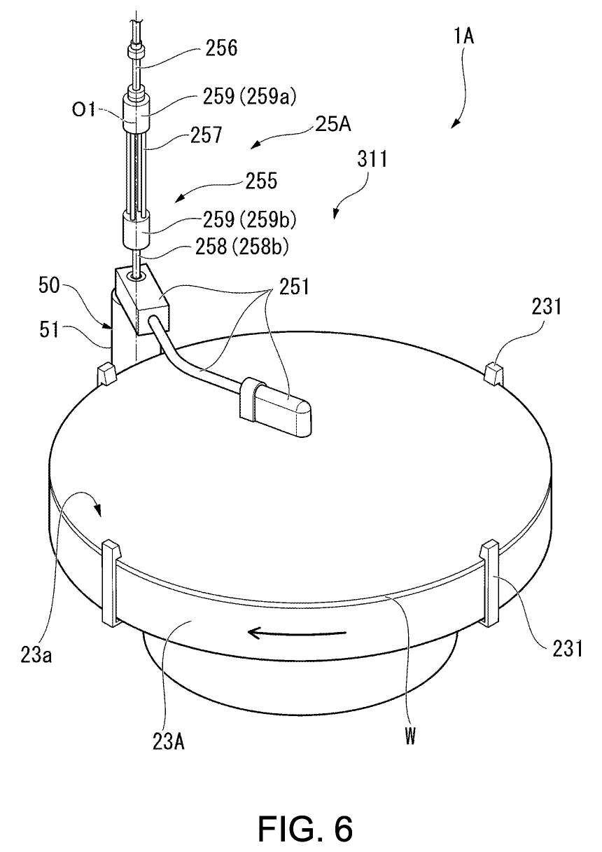

FIG. 6 is a perspective view showing a configuration of a washing module 311 provided in the substrate processing apparatus according to the second embodiment. Regarding the substrate processing apparatus 1A according to the present embodiment, descriptions of configurations common with the substrate processing apparatus 1 of the first embodiment will be omitted or will be described using the same reference signs, and differences will be mainly described.

The substrate processing apparatus 1A is a substrate washing apparatus that washes a surface of a substrate W such as a silicon wafer. The substrate processing apparatus 1A includes a washing module 311. As shown in FIG. 6, the washing module 311 includes a substrate processing table (washing table) 23A having an upper surface 23a, a supply line 25A for supplying a washing liquid (a utility such as pure water) to the upper surface 23a of the substrate processing table 23A, and a swing mechanism 50 that swings a swing arm 251 of the supply line 25A about a swing axis O1.

The supply line 25A includes a swing arm 251 and a utility supply part 255. In the present embodiment, the utility supply part 255 is inserted through the swing arm 251, and the swing arm 251 supports the utility supply part 255 inserted through the swing arm 251.

The substrate processing table 23A has multiple holding parts 231. The multiple holding parts 231 grip the substrate W placed on the upper surface 23a of the substrate processing table 23A and hold the substrate W on the upper surface 23a. The substrate W held by the multiple holding parts 231 does not detach from the upper surface 23a even when the substrate processing table 23A rotates on the table shaft.

In the example shown in FIG. 6, four holding parts 231 are provided, and the four holding parts 231 are disposed at equal intervals in a circumferential direction around the table shaft of the substrate processing table 23A. The number of the holding parts 231 provided may also be any number as long as the substrate W can be held on the upper surface 23a of the substrate processing table 23A. For example, the number of the holding part 231 provided may also be one only, or multiple holding parts 231 in a number other than four may also be provided.

As described above, in the present embodiment, while the utility supply part 255 supplying the utility to the substrate processing table 23A is provided, it is possible to provide a substrate processing apparatus 1A that enables swinging of the swing arm 251 through which the utility supply part 255 is inserted.

### Third Embodiment

Hereinafter, a dresser 26A according to a third embodiment of the disclosure will be described with reference to the drawings.

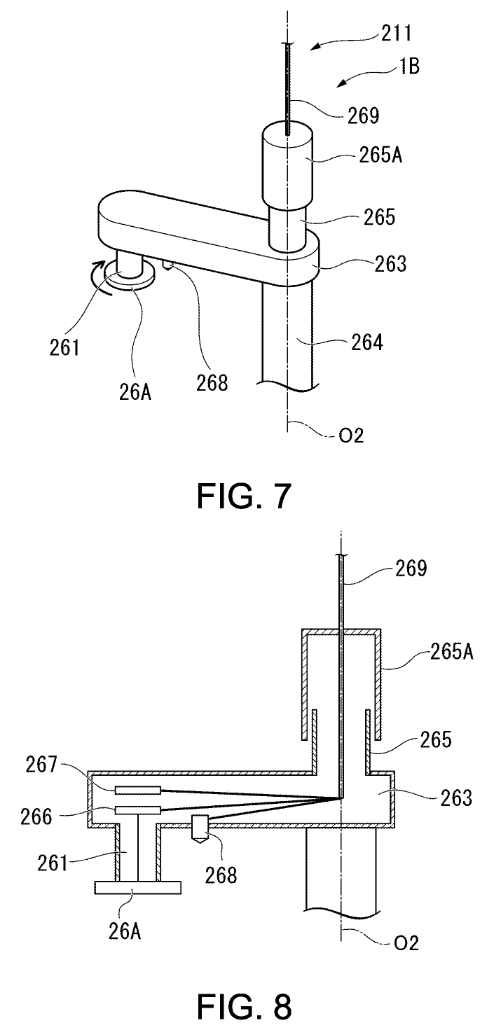

FIG. 7 is an enlarged perspective view showing a configuration of the dresser 26A according to the third embodiment. FIG. 8 is a cross-sectional view of a main part of the dresser 26A according to the third embodiment. Regarding a substrate processing apparatus 1B according to the present embodiment, descriptions of configurations common with the substrate processing apparatus 1 of the first embodiment will be omitted or will be described using the same reference signs, and differences will be mainly described.

The substrate processing apparatus 1B of the present embodiment has a polishing module 211. The polishing module 211 includes a dresser 26A in place of the dresser 26 of the first embodiment described above. The polishing module 211 of the substrate processing apparatus 1B of the present embodiment may or may not include the utility supply part (DIW supply part) 255 of the first embodiment.

The dresser 26A includes a shaft 261, a support arm (swing arm) 263, a first dresser cover 265, a second dresser cover 265A, a rotating motor 266, a lifting mechanism 267, a sensor 268, and a utility supply part 269. The dresser 26A is connected to the shaft 261, and the shaft 261 is rotatably attached to a tip of the support arm 263. The dresser 26A of the present embodiment may also include a dresser arm 262 similarly to the dresser 26 of the first embodiment.

The support arm 263 extends from outside the substrate processing table 23 toward a space above the substrate processing table 23. The support arm 263 is supported by a dresser swing mechanism 264 swingably about a swing axis O2.

The dresser swing mechanism 264 swings the support arm 263 about the swing axis O2. The dresser swing mechanism 264 is provided below the support arm 263. The dresser swing mechanism 264 may also be provided above the support arm 263.

The first dresser cover 265 and the second dresser cover 265A are each formed in a cylindrical shape that is hollow inside. A diameter of the first dresser cover 265 is smaller than a diameter of the second dresser cover 265A. Accordingly, the first dresser cover 265 is inserted through the second dresser cover 265A, and the second dresser cover 265A is disposed to cover an outer circumference of the first dresser cover 265. Therefore, the first dresser cover 265 and the second dresser cover 265A function as a seal (labyrinth seal) that prevents intrusion of foreign matter (e.g., water, dust, etc.) from outside into the second dresser cover 265A and the first dresser cover 265. It is also possible that the dresser 26A does not include the first dresser cover 265 and the second dresser cover 265A.

The rotating motor 266 rotates the dresser 26A. The lifting mechanism 267 lowers the dresser 26A and brings a lower surface of the dresser 26A into sliding contact with the rotating upper surface 23a of the substrate processing table 23. The sensor 268 monitors presence or absence of abnormality in the dresser 26A, or a state of the upper surface 23a of the substrate processing table 23.

The utility supply part 269 is inserted through the first dresser cover 265, the second dresser cover 265A, and the support arm 263. The utility supply part 269 supplies electricity as the utility to the rotating motor 266, the lifting mechanism 267, and the sensor 268 inside the support arm 263. That is, the utility supply part 269 is inserted through the support arm 263 from outside the support arm 263 and supplies the utility to the support arm 263.

A part (first portion) of the utility supply part 269 extends along the swing axis O2 and is positioned on the swing axis O2. In a view in the up-down direction (a view in the swing axis O2 direction), the first portion of the utility supply part 269 overlaps with the swing axis O2. In addition, another part (second portion) of the utility supply part 269 extends inside the support arm 263 and swings about the swing axis O2 together with the support arm 263.

The utility supply part 269 extends downward from above and then is inserted through the support arm 263 from an upper surface of the support arm 263. The utility supply part 269 may also extend upward from below and then be inserted through the support arm 263 from a lower surface of the support arm 263.

As described above, in the present embodiment, while the utility supply part 269 supplying the utility to the dresser 26A is provided, it is possible to provide a substrate processing apparatus 1B that enables swinging of the support arm 263 through which the utility supply part 269 is inserted.

Although exemplary embodiments of the disclosure have been described above, it is understood that such embodiments are illustrative embodiments of the disclosure and should not be considered as limiting. Additions, omissions, substitutions, and other modifications may be made without departing from the scope of the disclosure. Therefore, the disclosure is not considered as limited by the foregoing description, but is defined by the claims.

In the first embodiment, it has been described as an example that the supply line 25 includes only one slurry supply part 253, but the supply line 25 may also include multiple slurry supply parts 253. In such a case, the slurry dripping positions of the multiple slurry supply parts 253 may differ from each other. In addition, in such a case, inside the swing arm 251, the multiple slurry supply parts 253 may surround the utility supply part 255 (third utility piping 258, piping 258b).

In the first embodiment, it has been described as an example that the supply line 25 includes the slurry supply part 253, the dressing liquid supply part 254, and the utility supply part 255, but it is also possible that the supply line 25 does not include at least one of the slurry supply part 253 and the dressing liquid supply part 254. It is also possible that the supply line 25 does not include the slurry supply part 253 and the dressing liquid supply part 254, and only includes the utility supply part 255.

In the first embodiment, the slurry supply part 253, the dressing liquid supply part 254, the first utility piping 256, the multiple second utility pipings 257, and the third utility piping 258 (pipings 258b and 258c) may also be formed of materials other than flexible tube bodies, as long as the swing motion of the swing arm 251 about the swing axis O1 is allowed.

In the first embodiment, the slurry supply part 253, the dressing liquid supply part 254, the first utility piping 256, the multiple second utility pipings 257, and the third utility piping 258 (pipings 258b and 258c) may have only a part thereof formed of materials other than flexible tube bodies.

For example, only parts of the slurry supply part 253, the dressing liquid supply part 254, and the piping 258c of the third utility piping 258 that are exposed to outside on the lower surface of the swing arm 251 may be formed of materials other than flexible tube bodies, and the other portions thereof may be formed of flexible tube bodies.

For example, only parts of the first utility piping 256, the multiple second utility pipings 257, and the third utility piping 258 (pipings 258b and 258c) that are connected to other members (e.g., piping connection part 259 or joint 258a) may be formed of materials other than flexible tube bodies, and the other portions thereof may be formed of flexible tube bodies.

In the first embodiment and the second embodiment, the utility supply part 255 extends downward from above and then is inserted through the swing arm 251, and the swing mechanism 50 (shaft 51) is provided below the swing arm 251.

However, the utility supply part 255 may also extend downward from above and then be inserted through the swing arm 251, and the swing mechanism 50 (shaft 51) may also be provided above the swing arm 251.

In addition, the utility supply part 255 may also extend upward from below and then be inserted through the swing arm 251, and the swing mechanism 50 (shaft 51) may also be provided above the swing arm 251.

In addition, the utility supply part 255 may also extend upward from below and then be inserted through the swing arm 251, and the swing mechanism 50 (shaft 51) may also be provided below the swing arm 251.

In the first embodiment, the slurry supply part 253 and the dressing liquid supply part 254 extend downward from above and then are inserted through the swing arm 251. However, the slurry supply part 253 and the dressing liquid supply part 254 may also extend upward from below and then be inserted through the swing arm 251.

In the first embodiment, it has been described as an example that the supply line 25 provided separately from the atomizer 27 and the dresser 26 supplies the slurry, the dressing liquid, and the pure water to the substrate processing table 23. However, the atomizer 27 may also supply at least one of the slurry, the dressing liquid, and the pure water to the substrate processing table 23. That is, the supply line 25 may also be provided in the atomizer 27. In such a case, for example, the atomizer 27 functions as the swing arm 251, and at least one of the slurry supply part 253, the dressing liquid supply part 254, and the utility supply part 255 is inserted through inside of the atomizer 27. In this manner, by providing the supply line 25 in the atomizer 27, space can be saved.

In addition, in the first embodiment, the dresser 26 may also supply at least one of the slurry, the dressing liquid, and the pure water to the substrate processing table 23. That is, the supply line 25 may also be provided in the dresser 26. In such a case, for example, the dresser arm 262 and the support arm 263 of the dresser 26 function as the swing arm 251, and at least one of the slurry supply part 253, the dressing liquid supply part 254, and the utility supply part 255 is inserted through inside of the dresser arm 262 and the support arm 263. In this manner, by providing the supply line 25 in the dresser 26, space can be saved.

In the first embodiment and the second embodiment, it has been described as an example that the utility supply part 255 includes the first utility piping 256, the multiple second utility pipings 257, the third utility piping 258, and the multiple piping connection parts 259. However, it is also possible that the utility supply part 255 does not include the first utility piping 256, the multiple second utility pipings 257, and the multiple piping connection parts 259. In such a case, the upper end of the third utility piping 258 (piping 258b) is fixed in a non-rotatable manner, and pure water is supplied to the third utility piping 258 from outside.

In the first embodiment and the second embodiment, it has been described as an example that the utility supply part 255 supplies a large flow rate of pure water as the utility to the upper surface 23a of the substrate processing table 23. However, the utility supply part 255 may also supply utilities other than pure water.

For example, in the first embodiment, the utility supply part 255 may also supply a slurry as the utility to the upper surface 23a of the substrate processing table 23. In such a case, it is also possible that the supply line 25 does not include the slurry supply part 253.

For example, in the first embodiment, the utility supply part 255 may also supply a dressing liquid as the utility to the upper surface 23a of the substrate processing table 23. In such a case, it is also possible that the supply line 25 does not include the dressing liquid supply part 254.

For example, the utility supply part 255 may also supply a gas as the utility.

For example, the utility supply part 255 may also supply electricity as the utility (may be an electric wire).

For example, the utility supply part 255 may also supply vacuum as the utility (may be a vacuum generating apparatus that provides a vacuum state).

In the first embodiment and the second embodiment, it has been described as an example that the utility supply part 255 supplies the utility (large flow rate of pure water) to the upper surface 23a of the substrate processing table 23. However, the utility supply part 255 may also supply the utility to components or devices inside the swing arm 251. That is, the utility supply part 255 may also supply the utility to at least a part of the swing arm 251. In such a case, the utility supply part 255 may supply a gas, electricity, or vacuum as the utility.

For example, in the case where the dresser arm 262 and the support arm 263 of the dresser 26 function as the swing arm 251, the utility supply part 255 may supply the utility to components or devices (e.g., a motor provided in the dresser 26, various sensors such as an image sensor, or a lifting stage that lifts and lowers the sensor) inside the dresser arm 262 and the support arm 263. In such a case, the utility supply part 255 may supply a gas, electricity, or vacuum as the utility.

In the first embodiment, it has been illustrated that the utility supply part 255 supplying a large flow rate of pure water as the utility is applied to the polishing module 21 of the substrate processing apparatus 1. However, as in the second embodiment, the utility supply part 255 may also be applied to components other than the polishing module 21 of the substrate processing apparatus 1. For example, the utility supply part 255 may also be applied to the washing module 31 of the substrate processing apparatus 1. In addition, the utility supply part 255 may also be applied to a substrate processing apparatus (e.g., a back surface polishing apparatus, a bevel polishing apparatus, an etching apparatus, or a plating apparatus) other than a CMP apparatus. In addition, the utility supply part 255 may also be applied to the drying module 32. In such a case, the utility supply part 255 may supply a gas, electricity, or vacuum as the utility.

In addition, a configuration including the supply line 25 supplying the utility to outside may also be applied as a supply apparatus to a substrate processing apparatus or a configuration other than a substrate processing apparatus. In such a case, the supply apparatus may be a supply apparatus that supplies the utility to outside from the tip, and may include: a supply line 25 having a swing arm 251 that swings about the swing axis O1, and a utility supply part 255 that is inserted through the swing arm 251 from outside the swing arm 251 and supplies the utility to outside from the tip of the swing arm 251; and a swing mechanism 50 that swings the swing arm 251 about the swing axis O1. A part of the utility supply part 255 may extend along the swing axis O1 and may be positioned on the swing axis O1.

Among the first embodiment to the third embodiment, a substrate processing apparatus adopting a configuration combining configurations of multiple embodiments may also be adopted. For example, the washing module 311 of the second embodiment may also be applied to the washing module 31 of the substrate processing apparatus 1 of the first embodiment. For example, the polishing module 21 of the substrate processing apparatus 1 of the first embodiment may also include the dresser 26A of the third embodiment in place of the dresser 26.

What is claimed is:

1. A substrate processing apparatus comprising:
a substrate processing table;
a processing part applying a predetermined processing to a substrate placed on an upper surface of the substrate processing table;
a supply line comprising:
a swing arm extending from outside the substrate processing table toward a space above the substrate processing table; and
a utility supply part that is inserted through the swing arm from outside the swing arm and supplies a utility to the substrate placed on the upper surface of the substrate processing table; and
a swing mechanism swinging the swing arm about a swing axis, wherein
a part of the utility supply part extends along the swing axis and is positioned on the swing axis.

2. The substrate processing apparatus according to claim 1, wherein
the utility supply part comprises:
a first utility piping extending along the swing axis and positioned on the swing axis;
a plurality of second utility pipings extending along the swing axis and connected to the first utility piping;
a third utility piping that has a part extending along the swing axis and positioned on the swing axis, is connected to the plurality of second utility pipings, is inserted through the swing arm, and swings about the swing axis together with the swing arm;
a first piping connection part connecting the first utility piping and the plurality of second utility pipings; and
a second piping connection part connecting the plurality of second utility pipings and the third utility piping.

3. The substrate processing apparatus according to claim 2, wherein
the second utility piping has a higher flexibility than the first utility piping and the third utility piping.

4. The substrate processing apparatus according to claim 3, wherein
an outer diameter of the second utility piping is smaller than each of an outer diameter of the first utility piping and an outer diameter of the third utility piping.

5. The substrate processing apparatus according to claim 3, wherein
a total of flow path areas of the plurality of second utility pipings is 80% or more of each of a flow path area of the first utility piping and a flow path area of the third utility piping.

6. The substrate processing apparatus according to claim 2, wherein
an upper end of the first utility piping is fixed in a non-rotatable manner, and
upon swinging of the swing arm about the swing axis, the plurality of second utility pipings twist such that a position of an upper end and a position of a lower end of each of the plurality of second utility pipings differ from each other in a circumferential direction around the swing axis in a view in an up-down direction.

7. The substrate processing apparatus according to claim 2, wherein
in a view in an up-down direction, the plurality of second utility pipings are disposed to surround the swing axis.

8. The substrate processing apparatus according to claim 1, wherein
the utility supply part supplies a fluid as the utility.

9. The substrate processing apparatus according to claim 8, wherein
the utility supply part supplies pure water as the fluid.

10. The substrate processing apparatus according to claim 1, further comprising:
a polishing head, wherein
a polishing pad is attached to the upper surface of the substrate processing table, and a surface of the polishing pad forms a polishing surface for polishing the substrate, and
the polishing head holds the substrate serving as a polishing target to polish the substrate while pressing the substrate against the polishing surface of the polishing pad on the substrate processing table.

11. The substrate processing apparatus according to claim 10, wherein
the supply line further comprises a slurry supply part that is inserted through the swing arm from outside the swing arm and supplies a slurry to the upper surface of the substrate processing table.

12. The substrate processing apparatus according to claim 11, wherein
inside the swing arm, the slurry supply part crosses the utility supply part in a horizontal direction.

13. The substrate processing apparatus according to claim 11, wherein
a position on the upper surface of the substrate processing table at which the slurry supply part supplies the slurry is closer to a center of the substrate processing table than a position on the upper surface of the substrate processing table at which the utility supply part supplies the utility.

14. The substrate processing apparatus according to claim 11, wherein
inside the swing arm, at least a part of the utility supply part is disposed below the slurry supply part.

15. The substrate processing apparatus according to claim 1, wherein
the supply line is provided in the processing part.

16. The substrate processing apparatus according to claim 10, further comprising:
a dresser, wherein
the supply line is provided in the dresser.

17. A substrate processing apparatus comprising:
a substrate processing table;
a processing part applying a predetermined processing to a substrate placed on an upper surface of the substrate processing table;
a swing arm extending from outside the substrate processing table toward a space above the substrate processing table;
a utility supply part that is inserted through the swing arm from outside the swing arm and supplies a utility to the swing arm; and
a swing mechanism swinging the swing arm about a swing axis, wherein
a part of the utility supply part extends along the swing axis and is positioned on the swing axis.

18. A supply apparatus supplying a utility to outside from a tip, the supply apparatus comprising:
a supply line comprising:
a swing arm swinging about a swing axis; and
a utility supply part that is inserted through the swing arm from outside the swing arm and supplies the utility to outside from a tip of the swing arm; and
a swing mechanism swinging the swing arm about the swing axis, wherein
a part of the utility supply part extends along the swing axis and is positioned on the swing axis.
